(19) United States
(12) Patent Application Publication
(10) Pub. No.: US 2025/0372561 A1
(43) Pub. Date: Dec. 4, 2025

(54) SEMICONDUCTOR DEVICE AND METHOD OF MANUFACTURING SEMICONDUCTOR DEVICE

(71) Applicant: SUMITOMO ELECTRIC INDUSTRIES, LTD., Osaka (JP)

(72) Inventors: Yutaka MORIYAMA, Osaka (JP); Tatsuya HASHINAGA, Osaka (JP)

(21) Appl. No.: 19/217,078

(22) Filed: May 23, 2025

(30) Foreign Application Priority Data
Jun. 4, 2024 (JP) 2024-090464

(51) Int. Cl. H01L 23/00; H01L 23/31; H01L 23/66; H01L 25/18

(52) U.S. Cl. CPC H01L 24/24; H01L 23/3135; H01L 23/66; H01L 24/19; H01L 24/20; H01L 25/18; H01L 2223/6616; H01L 2223/6672; H01L 2224/19; H01L 2224/2101; H01L 2224/2105; H01L 2224/214; H01L 2224/215; H01L 2224/24195; H01L 2224/24265

(57) ABSTRACT

A semiconductor device includes a conductive base having a first main surface, a semiconductor chip provided at the first main surface and including a first electrode, a first insulating layer provided at the first main surface and covering the semiconductor chip; a first wiring layer provided above the first insulating layer and including a first wiring electrically connected to the first electrode, a second insulating layer provided above the first insulating layer and covering the first wiring layer, and a second wiring layer provided above the second insulating layer and including an external terminal electrically connected to the first wiring. The external terminal extends outward beyond a side surface of the second insulating layer in a plan view perpendicular to the first main surface.

### CROSS REFERENCE TO RELATED APPLICATIONS

This application claims priority based on Japanese Patent Application No. 2024-090464 filed on Jun. 4, 2024, and the entire contents of the Japanese patent application are incorporated herein by reference.

### TECHNICAL FIELD

The present disclosure relates to a semiconductor device and a method of manufacturing a semiconductor device.

### BACKGROUND

A semiconductor device has been proposed in which a semiconductor chip is mounted on a metal plate, the semiconductor chip is covered with an insulating layer, and a wiring electrically connected to the semiconductor chip is provided on the insulating layer.
Patent literature 1: Japanese Unexamined Patent Application Publication No. 2023-133675
Patent literature 2: Japanese Unexamined Patent Application Publication No. 2023-133676

### SUMMARY

A semiconductor device according to the present disclosure includes a conductive base having a first main surface, a semiconductor chip provided at the first main surface and including a first electrode, a first insulating layer provided at the first main surface and covering the semiconductor chip, a first wiring layer provided on the first insulating layer and including a first wiring electrically connected to the first electrode, a second insulating layer provided on the first insulating layer and covering the first wiring layer, and a second wiring layer provided on the second insulating layer and including an external terminal electrically connected to the first wiring. The external terminal extends outward beyond a side surface of the second insulating layer in a plan view perpendicular to the first main surface.

### BRIEF DESCRIPTION OF THE DRAWINGS

FIG. 1 is a cross-sectional view (part 1) illustrating a semiconductor device according to a first embodiment.

FIG. 2 is a cross-sectional view (part 2) illustrating the semiconductor device according to the first embodiment.

FIG. 3 is a plan view illustrating a method of manufacturing the semiconductor device according to the first embodiment.

FIG. 4 is a cross-sectional view (part 1) illustrating the method of manufacturing the semiconductor device according to the first embodiment.

FIG. 5 is a cross-sectional view (part 2) illustrating the method of manufacturing the semiconductor device according to the first embodiment.

FIG. 6 is a cross-sectional view (part 3) illustrating the method of manufacturing the semiconductor device according to the first embodiment.

FIG. 7 is a cross-sectional view (part 4) illustrating the method of manufacturing the semiconductor device according to the first embodiment.

FIG. 8 is a cross-sectional view (part 5) illustrating the method of manufacturing the semiconductor device according to the first embodiment.

FIG. 9 is a cross-sectional view (part 6) illustrating the method of manufacturing the semiconductor device according to the first embodiment.

FIG. 10 is a cross-sectional view (part 7) illustrating the method of manufacturing the semiconductor device according to the first embodiment.

FIG. 11 is a cross-sectional view (part 8) illustrating the method of manufacturing the semiconductor device according to the first embodiment.

FIG. 12 is a cross-sectional view (part 9) illustrating the method of manufacturing the semiconductor device according to the first embodiment.

FIG. 13 is a cross-sectional view (part 10) illustrating the method of manufacturing the semiconductor device according to the first embodiment.

FIG. 14 is a cross-sectional view (part 11) illustrating the method of manufacturing the semiconductor device according to the first embodiment.

FIG. 15 is a cross-sectional view illustrating an example of mounting the semiconductor device according to the first embodiment.

FIG. 16 is a cross-sectional view illustrating a semiconductor device according to a second embodiment.

FIG. 17 is a cross-sectional view (part 1) illustrating a semiconductor device according to a third embodiment.

FIG. 18 is a cross-sectional view (part 2) illustrating the semiconductor device according to the third embodiment.

FIG. 19 is a cross-sectional view (part 1) illustrating a method of manufacturing the semiconductor device according to the third embodiment.

FIG. 20 is a cross-sectional view (part 2) illustrating the method of manufacturing the semiconductor device according to the third embodiment.

FIG. 21 is a cross-sectional view (part 3) illustrating the method of manufacturing the semiconductor device according to the third embodiment.

FIG. 22 is a cross-sectional view illustrating a semiconductor device according to a fourth embodiment.

FIG. 23 is a cross-sectional view illustrating a semiconductor device according to a fifth embodiment.

FIG. 24 is a cross-sectional view illustrating a semiconductor device according to a sixth embodiment.

FIG. 25 is a cross-sectional view illustrating a semiconductor device according to a seventh embodiment.

### DETAILED DESCRIPTION

In recent years, the use of semiconductor devices has been expanding, and the demand for a structure with a degree of freedom in mounting semiconductor devices has been increasing.

According to the present disclosure, the degree of freedom in mounting can be improved.

### DESCRIPTION OF EMBODIMENTS OF PRESENT DISCLOSURE

First, embodiments of the present disclosure will be listed and described.
(1) A semiconductor device according to an aspect of the present disclosure includes a conductive base having a first main surface, a semiconductor chip provided at the first main 25 surface and including a first electrode, a first insulating layer provided at the first main surface and covering the semiconductor chip, a first wiring layer provided on the first insulating layer and including a first wiring electrically connected to the first electrode, a second insulating layer provided on the first insulating layer and covering the first wiring layer, and a second wiring layer provided on the second insulating layer and including an external terminal electrically connected to the first wiring. The external terminal extends outward beyond a side surface of the second insulating layer in a plan view perpendicular to the first main surface.

Since the external terminal extends outward beyond the side surface of the second insulating layer, the external terminal can be connected to a terminal of a printed wiring board while the semiconductor device is accommodated inside an opening formed in the printed wiring board, for example. Thus, the degree of freedom in mounting can be improved.
(2) In (1), a dielectric loss of the first insulating layer may be lower than a dielectric loss of the second insulating layer. In this case, since good high frequency characteristics can be obtained by the first insulating layer, the degree of freedom in selecting the material of the second insulating layer is high. Thus, a material that is more easily dissolved in an alkaline solution than the first insulating layer can be used as the material of the second insulating layer, and the second insulating layer is easily processed.
(3) In (2), the second insulating layer may include an opening reaching the first wiring. In this case, the opening can be formed using an alkaline solution.
(4) In (3), the semiconductor device may further include a conductive layer provided at a bottom surface and a side wall surface of the opening, the conductive layer being in contact with the first wiring and the external terminal. In this case, the electrical resistance between the first wiring and the external terminal can be reduced. In addition, the conductive layer can improve a heat dissipation property.
(5) In (4), the semiconductor device may further include a sintered metal provided on the conductive layer. In this case, the electrical resistance can be further reduced, and the heat dissipation property can be further improved.
(6) In (4), the semiconductor device may further include a third insulating layer provided on the conductive layer. A dielectric loss of the third insulating layer may be lower than the dielectric loss of the second insulating layer. In this case, the conductive layer can be protected from the entry of moisture from the outside by the third insulating layer.
(7) In any one of (3) to (6), the semiconductor device may further include a covering member covering the opening. In this case, the conductive layer can be protected from the entry of moisture from the outside by the covering member.
(8) In any one of (1) to (7), the semiconductor device may further include a molding member covering the second wiring layer, the second insulating layer, the first wiring layer, and the first insulating layer. In this case, the conductive layer can be protected from the entry of moisture from the outside by the molding member.
(9) In any one of (2) to (7), the semiconductor device may further include a molding member covering the second wiring layer, the second insulating layer, the first wiring layer, and the first insulating layer. A dielectric loss of the molding member may be lower than the dielectric loss of the second insulating layer. In this case, the conductive layer can be protected from the entry of moisture from the outside by the molding member. Further, even if a molding member is present, good high frequency characteristics can be obtained.
(10) In any one of (1) to (9), the second wiring layer may include a second wiring. The semiconductor device may include an electronic component electrically connected to the second wiring. In this case, more electronic components can be included in the semiconductor device.
(11) In (10), the semiconductor chip may include a second electrode. The first wiring layer may include a third wiring electrically connected to the second electrode and the second wiring. In this case, the second electrode and the electronic component can be electrically connected to each other.
(12) A method of manufacturing a semiconductor device according to an aspect of the present disclosure includes providing a semiconductor chip at a first main surface of a conductive base having the first main surface, the semiconductor chip including a first electrode, providing a first insulating layer at the first main surface configured to cover the semiconductor chip, providing a first wiring layer on the first insulating layer, the first wiring layer including a first wiring electrically connected to the first electrode, providing a second insulating layer on the first insulating layer configured to cover the first wiring layer, and providing a second wiring layer on the second insulating layer, the second wiring layer including an external terminal electrically connected to the first wiring. The external terminal extends outward beyond a side surface of the second insulating layer in a plan view perpendicular to the first main surface.

According to this method, a semiconductor device that can improve the degree of freedom in mounting as described above can be manufactured.

### DETAILS OF EMBODIMENTS OF PRESENT DISCLOSURE

Hereinafter, embodiments of the present disclosure will be described in detail, but the present disclosure is not limited thereto. In the specification and the drawings, components having substantially the same functional configuration are denoted by the same reference numerals, and redundant description thereof may be omitted.

### First Embodiment

First, a first embodiment will be described. The first embodiment relates to a semiconductor device including a semiconductor chip.

### [Configuration of Semiconductor Device]

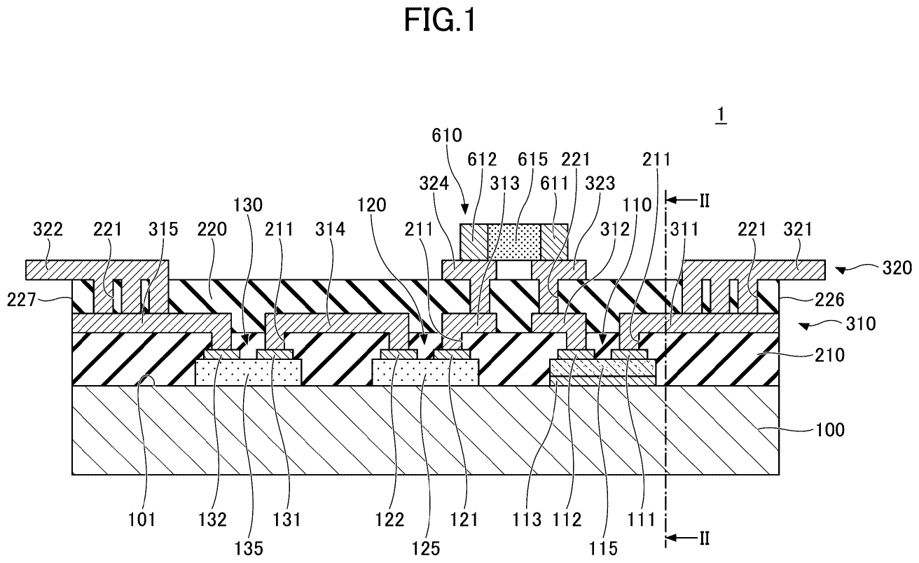

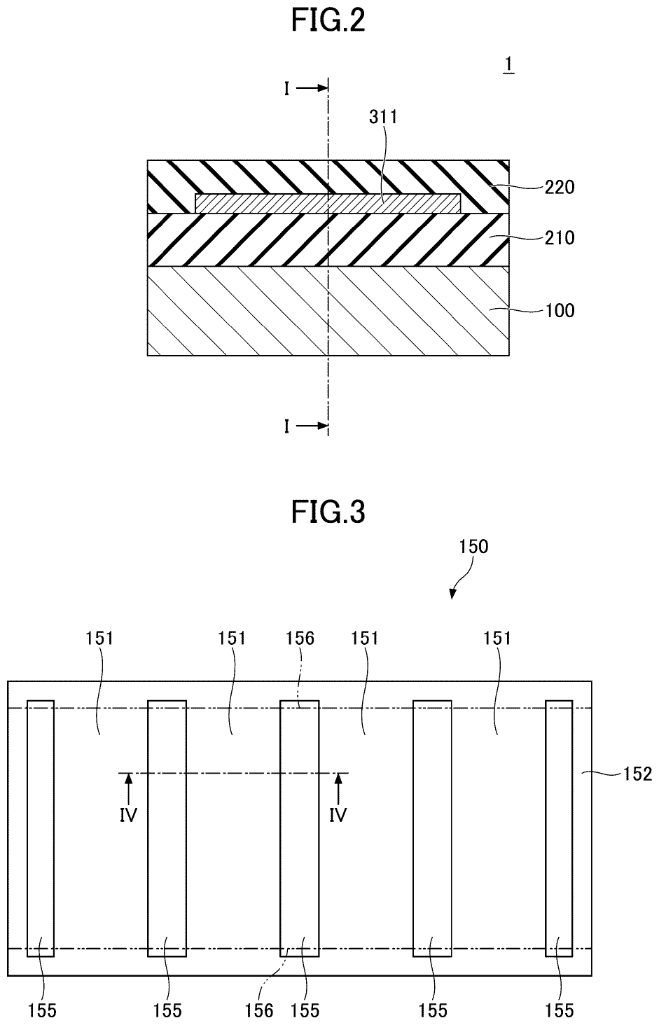

A configuration of the semiconductor device according to the first embodiment will be described. FIGS. 1 and 2 are cross-sectional views illustrating the semiconductor device according to the first embodiment. FIG. 1 corresponds to a cross-sectional view taken along line I-I in FIG. 2, and FIG. 2 corresponds to a cross-sectional view taken along line II-II in FIG. 1.

As illustrated in FIGS. 1 and 2, a semiconductor device 1 according to the first embodiment includes a metal plate 100, chips 110, 120, and 130, a first insulating layer 210, a first wiring layer 310, a second insulating layer 220, a second wiring layer 320, and an electronic component 610.

The material of the metal plate 100 is, for example, copper (Cu) or a copper alloy. The copper alloy is, for example, a copper-iron (Fe) alloy. The thickness of the metal plate 100 is, for example, 800 μm to 1400 μm. The metal plate 100 has a first main surface 101. The metal plate 100 is an example of a conductive base.

The chips 110, 120, and 130 are provided at the first main surface 101. For example, the chip 110 is a semiconductor chip including a transistor, and the chips 120 and 130 are capacitor chips.

The chip 110 includes a body portion 115 and electrodes 111, 112, and 113. The transistor is, for example, a gallium nitride (GaN)-based high-electron-mobility transistor (HEMT). For example, the electrode 111 is connected to the drain of the transistor, the electrode 112 is connected to the gate of the transistor, and the electrode 113 is connected to the source of the transistor. The electrode 113 is mechanically joined to the metal plate 100 and is electrically connected to the metal plate 100. The electrodes 111 and 112 are provided on a surface of the body portion 115 opposite to the surface facing the electrode 113. The chip 110 is an example of a semiconductor chip, the electrode 111 is an example of a first electrode, and the electrode 112 is an example of a second electrode.

The chip 120 includes a body portion 125 and electrodes 121 and 122, and the chip 130 includes a body portion 135 and electrodes 131 and 132. The electrodes 121 and 122 are provided on a surface of the body portion 125 opposite to the surface facing the first main surface 101. The electrodes 131 and 132 are provided on a surface of the body portion 135 opposite to the surface facing the first main surface 101.

The first insulating layer 210 is provided on or above the first main surface 101 and covers the chips 110, 120, and 130. The thickness of the first insulating layer 210 is, for example, 100 μm to 300 μm. The first insulating layer 210 contains, for example, an epoxy resin. For example, the relative dielectric constant of the first insulating layer 210 is 3.0 to 3.7 at 6 GHZ, and the dielectric loss is 0.007 or less at 6 GHz. The first insulating layer 210 may contain a filler, such as silica.

A plurality of via holes 211 are formed in the first insulating layer 210. One via hole 211 reaches the electrode 111, and one via hole 211 reaches the electrode 112. One via hole 211 reaches the electrode 121, and one via hole 211 reaches an electrode 122. One via hole 211 reaches the electrode 131, and one via hole 211 reaches the electrode 132.

The first wiring layer 310 is provided on or above the first insulating layer 210. The first wiring layer 310 includes wirings 311, 312, 313, 314, and 315. The wiring 311 is electrically connected to the electrode 111 through one via hole 211. The wiring 312 is electrically connected to the electrode 112 through one via hole 211. The wiring 313 is electrically connected to the electrode 121 through one via hole 211. The wiring 314 is electrically connected to the electrode 122 through one via hole 211 and is connected to the electrode 131 through another via hole 211. The wiring 315 is electrically connected to the electrode 132 through one via hole 211. The thickness of the first wiring layer 310 on or above the first insulating layer 210 is, for example, 35 μm to 45 μm. The material of the first wiring layer 310 is, for example, copper. The first wiring layer 310 is a redistribution layer. The wiring 311 is an example of a first wiring, and the wiring 312 is an example of a third wiring.

The second insulating layer 220 is disposed on or above the first insulating layer 210 and covers the first wiring layer 310. The thickness of the second insulating layer 220 is, for example, 50 μm to 200 μm. The second insulating layer 220 contains, for example, an epoxy resin. The dielectric loss of the second insulating layer 220 may be higher than the dielectric loss of the first insulating layer 210. For example, the relative dielectric constant of the second insulating layer 220 is 3.0 to 4.4 at 6 GHz, and the dielectric loss is 0.04 or less at 6 GHz. The second insulating layer 220 may contain a filler, such as silica.

A plurality of via holes 221 are formed in the second insulating layer 220. The plurality of via holes 221 reach the wiring 311, and one via hole 221 reaches the wiring 312. One via hole 221 reaches the wiring 313, and the plurality of via holes 221 reach the wiring 315.

The second wiring layer 320 is provided on or above the second insulating layer 220. The second wiring layer 320 includes external terminals 321 and 322 and wirings 323 and 324. The external terminal 321 is electrically connected to the wiring 311 through the plurality of via holes 221. The external terminal 322 is electrically connected to the wiring 315 through the plurality of via holes 221. The wiring 323 is electrically connected to the wiring 312 through one via hole 221. The wiring 324 is electrically connected to the wiring 313 through one via hole 221. The thickness of the second wiring layer 320 on the second insulating layer 220 is, for example, 80 μm to 200 μm. The material of the second wiring layer 320 is, for example, copper. The second wiring layer 320 is a redistribution layer. The wiring 323 is an example of a second wiring.

The external terminal 321 extends outward beyond one side surface 226 of the second insulating layer 220 in a plan view perpendicular to the first main surface 101. In addition, the external terminal 322 extends outward beyond a side surface 227 of the second insulating layer 220 opposite to the side surface 226 in a plan view perpendicular to the first main surface 101.

The electronic component 610 is connected to the wirings 323 and 324. For example, the electronic component 610 may be a surface mount device (SMD), a discrete component, such as a chip capacitor, a chip inductor, or a chip resistor. The electronic component 610 includes a body portion 615 and electrodes 611 and 612. The electrode 611 is connected to the wiring 323, and the electrode 612 is connected to the wiring 324.

### [Method of Manufacturing Semiconductor Device]

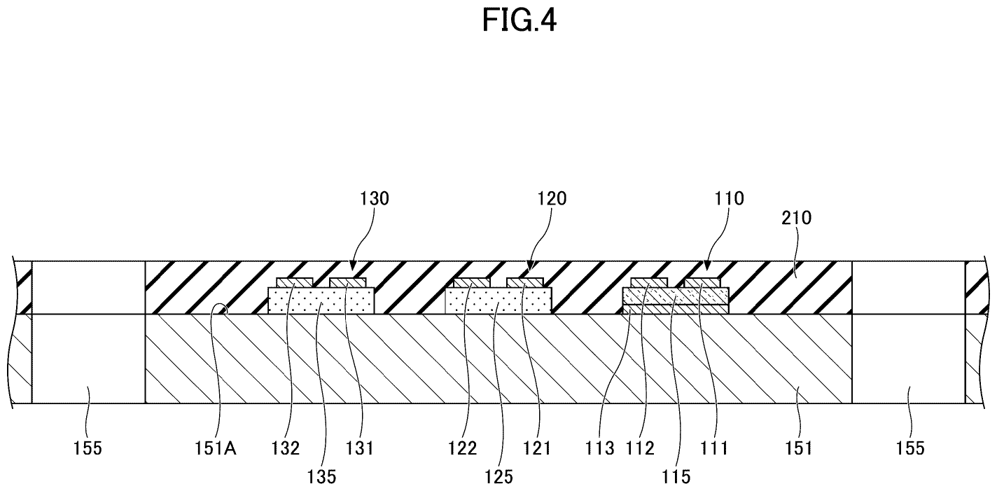

A method of manufacturing the semiconductor device according to the first embodiment will be described. FIG. 3 is a plan view illustrating the method of manufacturing the semiconductor device according to the first embodiment. FIGS. 4 to 14 are cross-sectional views illustrating the method of manufacturing the semiconductor device according to the first embodiment. FIGS. 4 to 14 correspond to cross-sectional views taken along line IV-IV in FIG. 3.

First, as illustrated in FIG. 3, a lead frame 150 is prepared. The lead frame 150 includes a plurality of main portions 151 and a plurality of frame portions 152. In a plan view, the frame portion 152 has an inner edge and an outer edge of a rectangular shape. The main portion 151 has a rectangular shape having a long side and a short side in a plan view. The plurality of main portions 151 are arranged in parallel to each short side. In a direction parallel to the short sides of the main portion 151, there are slits 155 between adjacent main portions 151 and between the main portion 151 and the frame portion 152. Subsequently, the lead frame 150 and the layer provided on or above the lead frame 150 are cut along a cutting-plane line 156. The cutting-plane line 156 extends along the short side of the main portion 151 in the vicinity of each of both short sides of the main portion 151 and intersects with the slit 155.

Next, as illustrated in FIG. 4, the chips 110, 120 and 130 are provided at an upper surface 151A of the main portion 151. The chips 110, 120, and 130 can be fixed to the upper surface 151A, using a conductive adhesive, such as nano-silver (Ag) paste. Next, the first insulating layer 210 is formed on or above the upper surface (including the upper surface 151A) of the lead frame 150 to cover the chips 110, 120, and 130. In the formation of the first insulating layer 210, for example, a material is supplied using a mold and temporarily cured. As a material of the first insulating layer 210, an organic resin material that does not dissolve in a strong alkaline solution and a strong acidic solution in a short time of about 30 minutes after the main curing and that has a higher thermal decomposition temperature than the temperature of the main curing of the second insulating layer 220 is used. Examples of such a material include (1) a resin composition containing a bisphenol F epoxy resin (about 2% by mass), aniline (about 3% by mass), and silica particles (90% by mass or more), and (2) a resin composition containing an epoxy resin (5% by mass to 10% by mass), a phenol resin (1% by mass to 5% by mass), and silica particles (70% by mass or more). A glass transition temperature Tg of these resin compositions is in the range of 100° C. to 200° C., and the main curing conditions under which the crosslinking reaction of the epoxy resin is saturated are in the range of 150° C. to 230° C. and 1 hour to 5 hours.

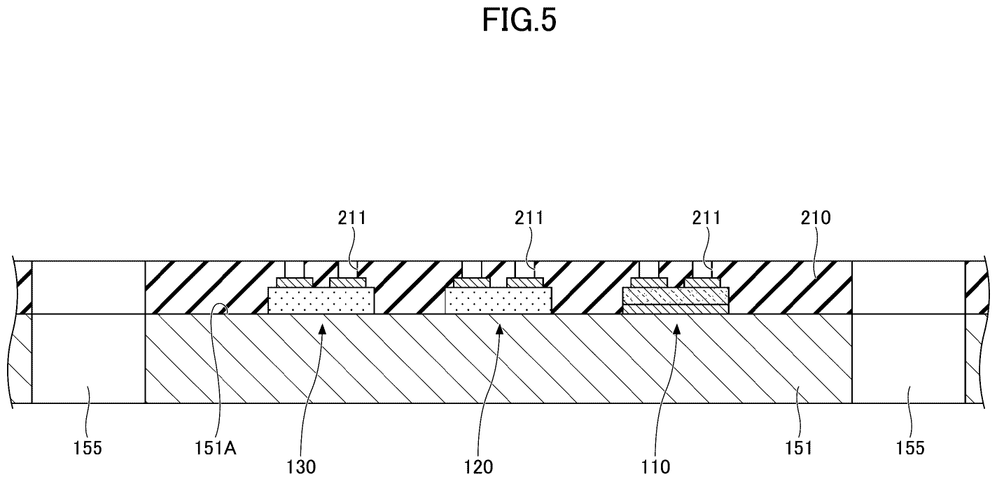

Next, as illustrated in FIG. 5, the plurality of via holes 211 are formed in the first insulating layer 210. The via hole 211 can be formed by, for example, laser light irradiation. After the via hole 211 is formed, desmear processing is performed.

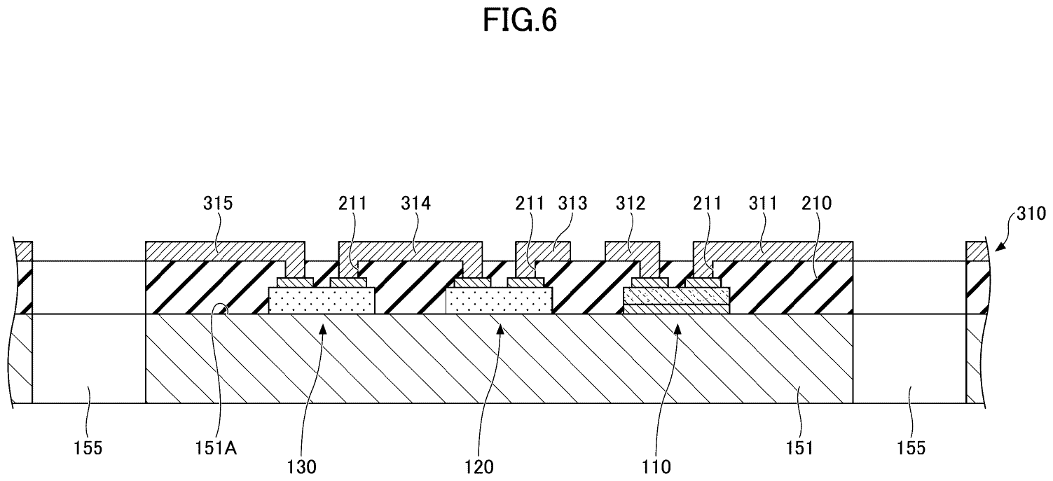

Next, as illustrated in FIG. 6, the first wiring layer 310 that includes the wirings 311, 312, 313, 314 and 315 is formed. In the formation of the first wiring layer 310, for example, the formation of an electroless plating layer (seed layer), the formation of a mask on the seed layer, the formation of an electrolytic plating layer, the removal of the mask, and the flash etching of the seed layer are performed in this order. Thereafter, the main curing of the first insulating layer 210 is performed. Since the mask is subjected to the pressure of a chemical solution in a subsequent wet process, a spacer may be provided in the slit 155 in the lead frame 150 between the formation of the electroless plating layer and the formation of the mask for the purpose of maintaining the flatness of the mask.

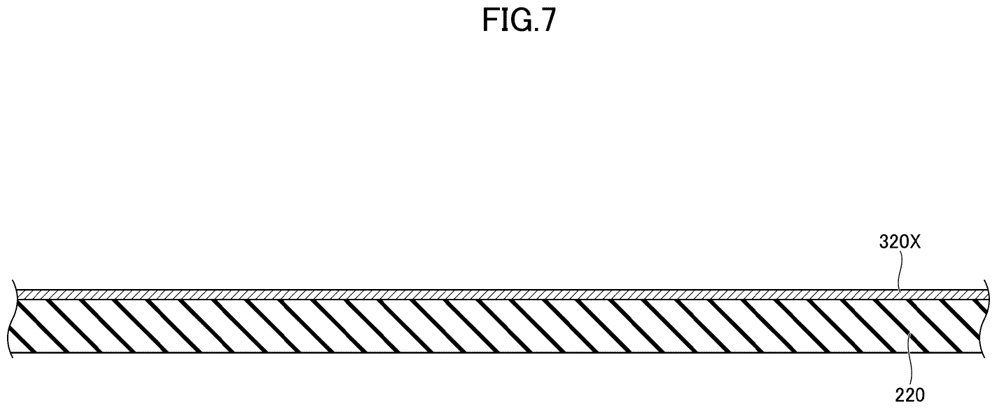

As illustrated in FIG. 7, a laminate of the second insulating layer 220 and a metal foil 320X is prepared. The metal foil 320X may be subjected to a roughening treatment in advance, and irregularities having a depth of about 1 μm may be formed on the surface of the metal foil 320X after the roughening treatment. For example, the metal foil 320X is a copper foil, and the thickness of the metal foil 320X is 80 μm to 200 μm. The metal foil 320X and the second insulating layer 220 may be stacked on each other by thermal compression.

As a material of the second insulating layer 220, for example, a material that dissolves in an alkaline solution after the main curing is used. As such a material, a novolac epoxy acrylate having a carboxyl group is exemplified. The novolac epoxy acrylate has excellent heat resistance and electrical properties, and is soluble in an alkaline solution. The novolac epoxy acrylate is obtained, for example, by adding acrylic acid or methacrylic acid to 90% or more of the epoxy groups of a phenol novolac epoxy or a cresol novolac epoxy having a weight-average molecular weight of 1000 or more, and adding an acid anhydride to the hydroxyl groups produced here.

As the material of the second insulating layer 220, a material that dissolves in an alkaline solution in a temporarily cured state may be used. Examples of such a material include a thermosetting epoxy resin such as a bisphenol A epoxy resin. In the case where the epoxy resin is in a temporarily cured state in which the crosslinking reaction between the epoxy group in the resin and the curing agent (modified diamine, phenol compound, or the like) is not saturated, the thermosetting epoxy resin can also be dissolved in the alkaline solution.

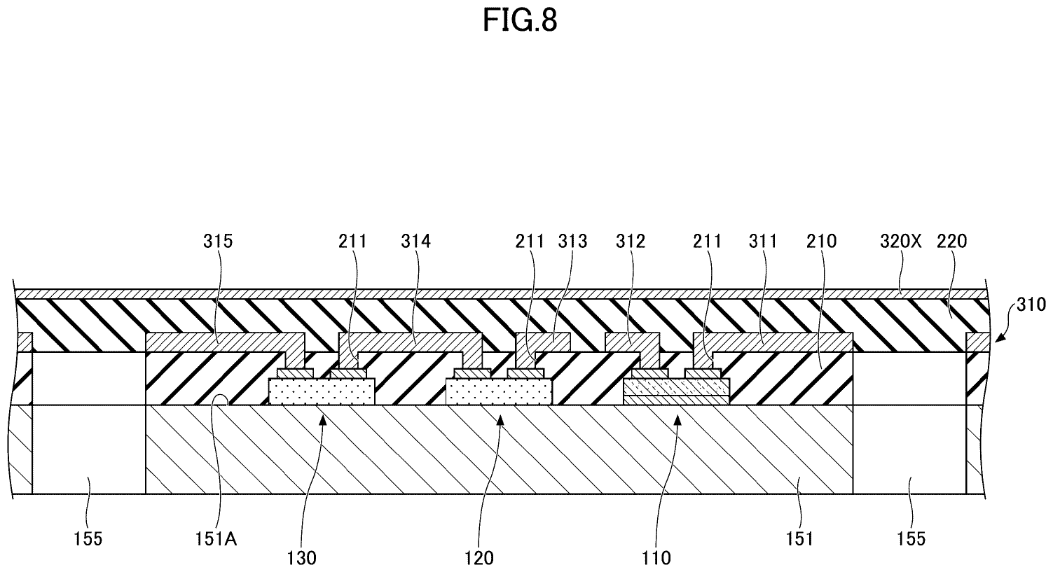

Next, as illustrated in FIG. 8, the laminate of the second insulating layer 220 and the metal foil 320X is bonded to the first insulating layer 210 and the first wiring layer 310 so as to cover the first insulating layer 210 and the first wiring layer 310 on each main portion 151 and the slit 155. The second insulating layer 220 is in contact with the first insulating layer 210 and the first wiring layer 310.

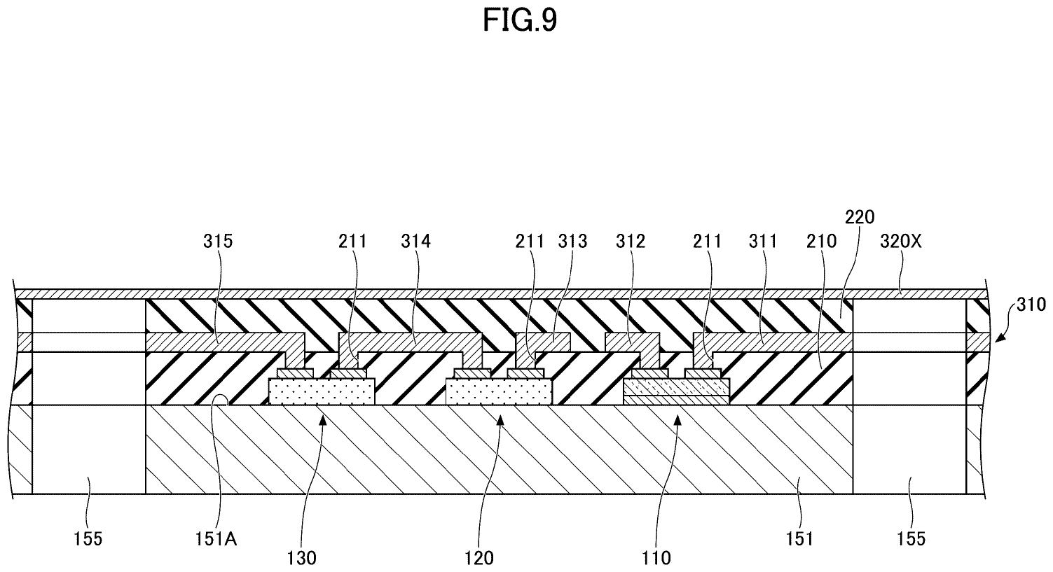

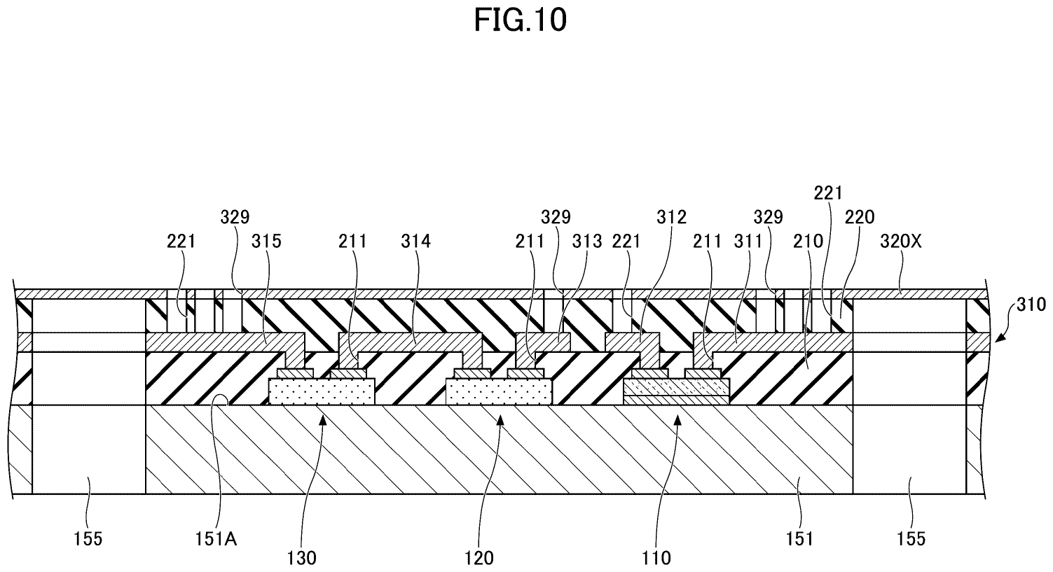

Next, as illustrated in FIG. 9, a portion of the second insulating layer 220 overlapping the slit 155 in a plan view is removed. Next, the main curing of the second insulating layer 220 is performed. Since the thermal decomposition temperature of the material of the first insulating layer 210 is higher than the temperature of the main curing of the second insulating layer 220, the first insulating layer 210 is not thermally decomposed during the main curing of the second insulating layer 220. When a material that dissolves in an alkaline solution in a temporarily cured state is used as the material of the second insulating layer 220, the second insulating layer 220 is set to be in a temporarily cured state.

Next, as illustrated in FIG. 10, a plurality of openings 329 are formed in the metal foil 320X, and the plurality of via holes 221 are formed in the second insulating layer 220, using the metal foil 320X in which the openings 329 are formed as an etching mask. The opening 329 is formed above a region where the via hole 221 is to be formed. The opening 329 can be formed by, for example, wet etching (window etching) using an acidic solution containing cupric chloride. The via hole 221 can be formed by, for example, laser light irradiation. The via hole 221 can be formed by wet etching using, for example, an alkaline solution, using the metal foil 320X in which the opening 329 is formed as an etching mask. As the alkaline solution, for example, an alkaline solution containing potassium hydroxide as a main component is used. The material of the first insulating layer 210 does not dissolve in a strong alkaline solution in a short time of about 30 minutes because the polymerization reaction and the crosslinking reaction of the functional group are saturated in the resin after the main curing. Thus, the first insulating layer 210 does not dissolve when the via hole 221 is formed using the alkaline solution. After the via hole 221 is formed, desmear processing including roughening of the side wall surface of the via hole 221 is performed. Due to the desmear processing, the electroless plating layer more easily adheres to the side wall surface of the via hole 221 afterwards.

When a material that dissolves in an alkaline solution after the main curing is used as the material of the second insulating layer 220, the opening 329 is formed so that the second insulating layer 220 does not excessively dissolve when the via hole 221 is formed. In addition, when a material that dissolves in an alkaline solution in a temporarily cured state is used as the material of the second insulating layer 220, the main curing of the second insulating layer 220 is performed after the formation of the via hole 221 and before the desmear processing so that the second insulating layer 220 does not dissolve in the desmear processing.

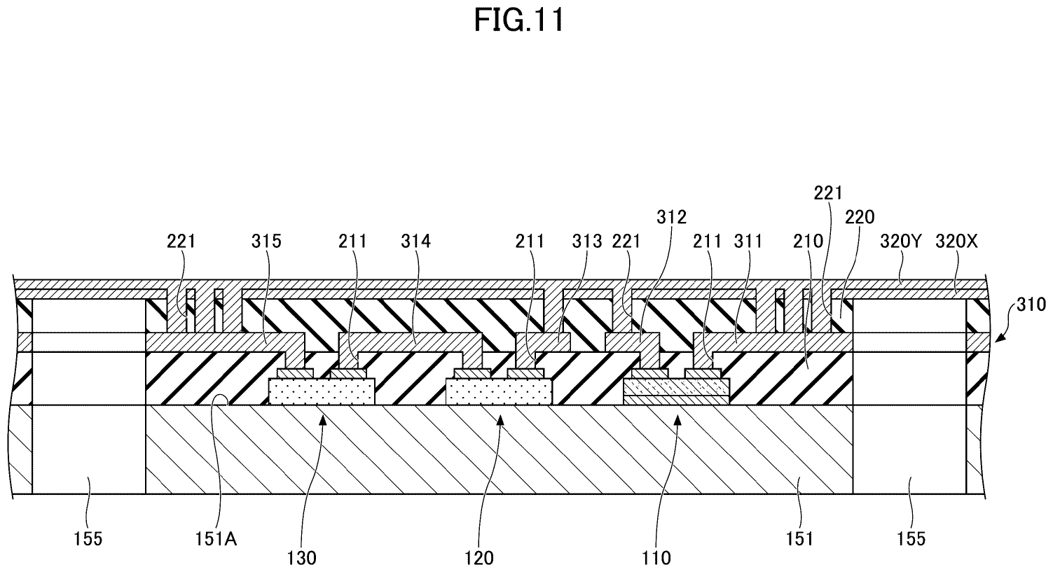

Next, as illustrated in FIG. 11, a plating layer 320Y is formed to fill each opening 329 and each via hole 221. The plating layer 320Y is also formed on or above the metal foil 320X. The thickness of the plating layer 320Y on the metal foil 320X is, for example, 10 μm to 50 μm. In the formation of the plating layer 320Y, for example, the formation of an electroless plating layer (seed layer) and the formation of an electrolytic plating layer are performed in this order. As the electroless plating layer, for example, a copper layer having a thickness of 0.1 μm to 1 μm is formed.

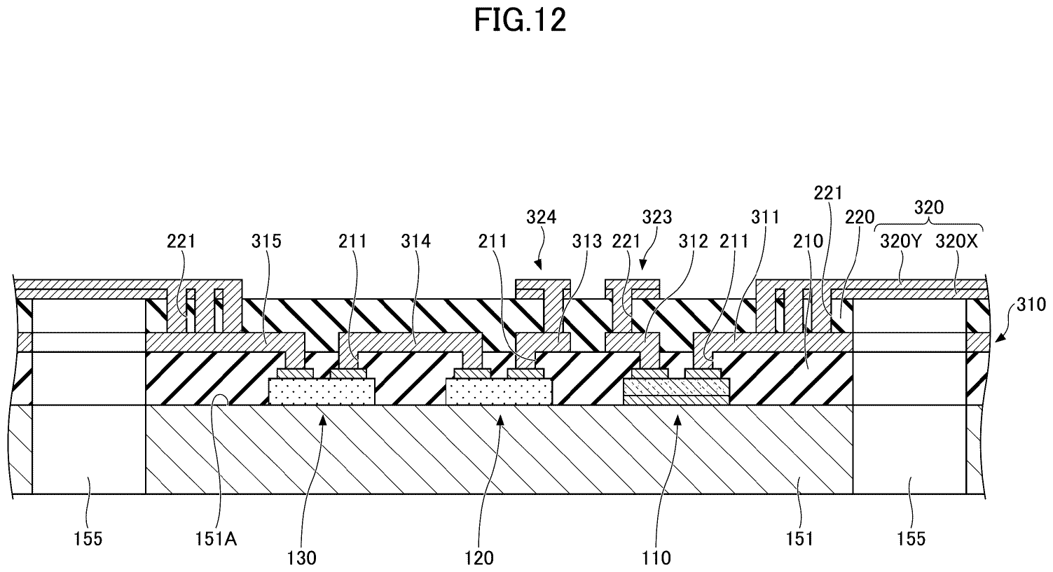

Next, as illustrated in FIG. 12, a laminate of the metal foil 320X and the plating layer 320Y is patterned to form the wirings 323 and 324, a portion to be the external terminal 321, and a portion to be the external terminal 322. In patterning the laminate of the metal foil 320X and the plating layer 320Y, wet etching using an acidic solution containing cupric chloride is performed, for example.

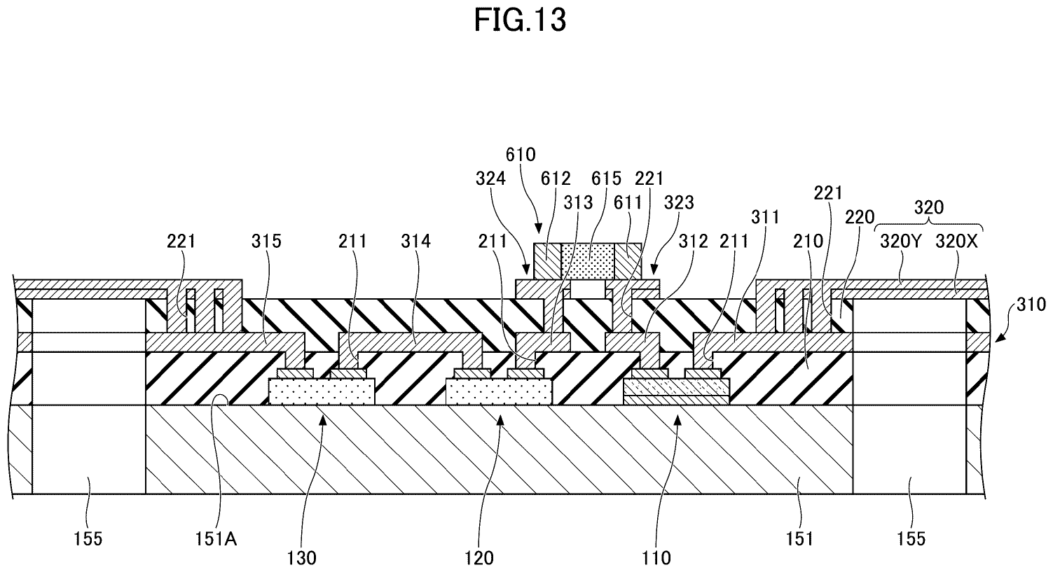

Next, as illustrated in FIG. 13, the electronic component 610 is mounted. At this time, the electrode 611 is connected to the wiring 323, and the electrode 612 is connected to the wiring 324.

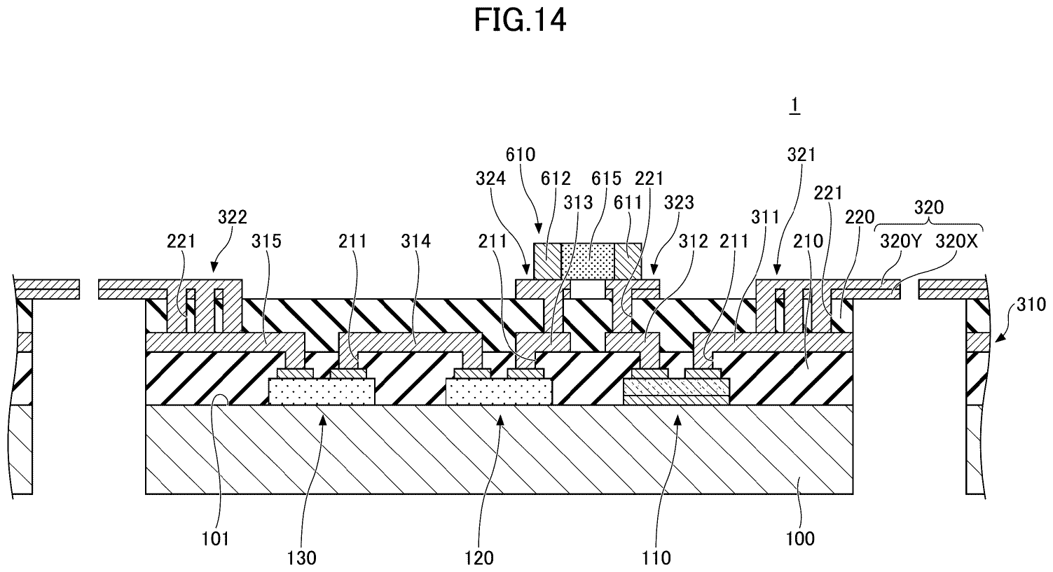

Next, as illustrated in FIG. 14, the laminate of the metal foil 320X and the plating layer 320Y is cut by etching in a region overlapping the slit 155 in a plan view. As a result, the external terminals 321 and 322 are obtained. Further, the lead frame 150 and the layer provided on or above the lead frame 150 are cut along the cutting-plane line 156 (see FIG. 3). As a result, the main portion 151 is separated from the frame portion 152, and the metal plate 100 is obtained.

In this way, the semiconductor device 1 according to the first embodiment can be manufactured.

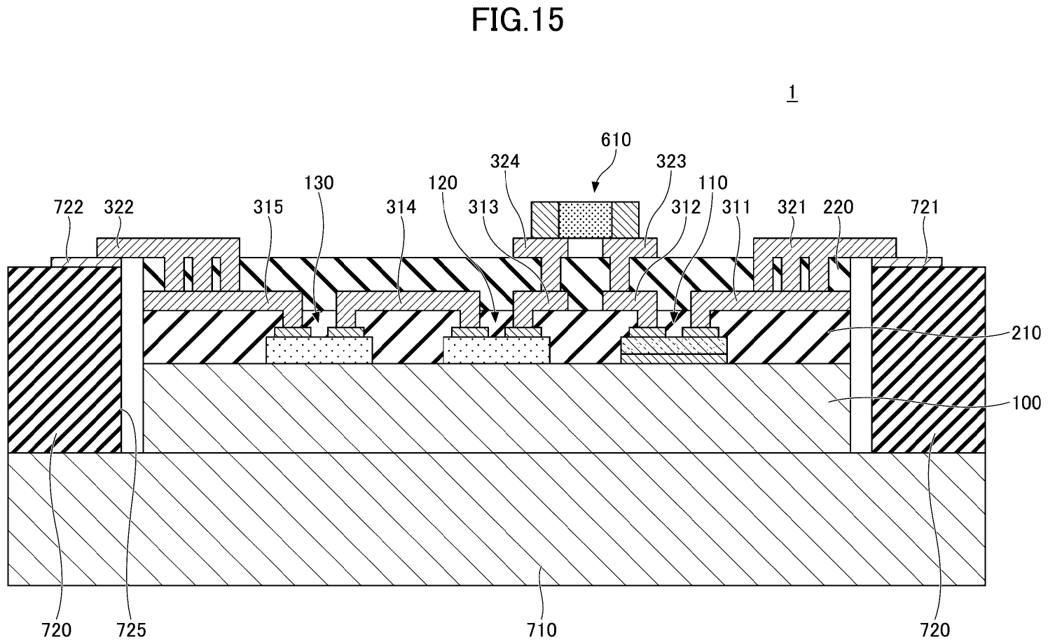

The semiconductor device 1 can be used, for example, as illustrated in FIG. 15, by housing the semiconductor device 1 inside an opening 725 formed in a printed wiring board 720 provided on a heat sink 710 having a flat upper surface, and bringing the metal plate 100 into contact with the heat sink 710. In this example, the external terminal 321 is connected to a terminal 721 of the printed wiring board 720, and the external terminal 322 is connected to a terminal 722. FIG. 15 is a cross-sectional view illustrating an example of mounting the semiconductor device 1 according to the first embodiment.

Since the external terminal 321 extends outward beyond the side surface 226 of the second insulating layer 220 and the external terminal 322 extends outward beyond the side surface 227, the external terminal 321 can be connected to the terminal 721 of the printed wiring board 720 and the external terminal 322 can be connected to the terminal 722 while the semiconductor device 1 is accommodated inside the opening 725 formed in the printed wiring board 720. Further, the metal plate 100 is brought into contact with the heat sink 710, and thus heat generated in the semiconductor device 1 can be released to the outside through the heat sink 710. Further, the ground potential can be applied to the semiconductor device 1 through the heat sink 710. In this way, the degree of freedom in mounting can be improved.

Since the dielectric loss of the first insulating layer 210 is lower than the dielectric loss of the second insulating layer 220, the first insulating layer 210 can provide good high frequency characteristics, and thus the degree of freedom in selecting the material of the second insulating layer 220 is high. Thus, a material that dissolves more easily in an alkaline solution than the first insulating layer 210 can be used as the material of the second insulating layer 220, and the second insulating layer 220 is easily processed. For example, the via hole 221 may be formed using an alkaline solution.

The second wiring layer 320 includes the wiring 323 and the semiconductor device 1 includes the electronic component 610 electrically connected to the wiring 323, so that the semiconductor device 1 can include more electronic components. In addition, the first wiring layer 310 includes the wiring 312 electrically connected to the electrode 112 of the chip 110 and the wiring 323, and thus the electrode 112 and the electronic component 610 can be electrically connected to each other.

### Second Embodiment

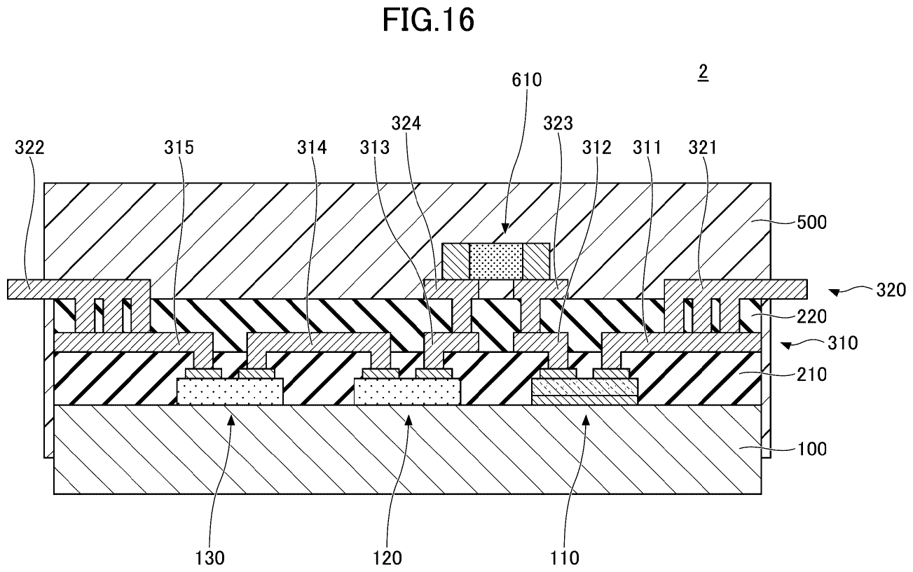

Next, a second embodiment will be described. The second embodiment is different from the first embodiment mainly in that it includes a molding member. FIG. 16 is a cross-sectional view illustrating a semiconductor device according to the second embodiment.

A semiconductor device 2 according to the second embodiment includes a molding member 500 as illustrated in FIG. 16. The molding member 500 covers the electronic component 610, the second wiring layer 320, the second insulating layer 220, the first wiring layer 310, and the first insulating layer 210. The thickness of the molding member 500 on the second insulating layer 220 is, for example, 1000 μm to 3000 μm. The dielectric loss of the molding member 500 may be lower than the dielectric loss of the second insulating layer 220. The molding member 500 contains, for example, an epoxy resin. For example, the relative dielectric constant of the molding member 500 is 3.0 to 3.7 or less at 6 GHz, and the dielectric loss is 0.007 or less at 6 GHZ. The molding member 500 may contain a filler, such as silica. The molding member 500 may be formed after the semiconductor device 1 is completed. The molding member 500 may be formed of the same material as the first insulating layer 210.

Other configurations of the second embodiment are the same as those of the first embodiment.

The second embodiment can also provide the same effect as the first embodiment. Further, according to the second embodiment, the electronic component 610, the second wiring layer 320, the second insulating layer 220, the first wiring layer 310, and the first insulating layer 210 can be protected from the entry of moisture from the outside.

### Third Embodiment

Next, a third embodiment will be described. The third embodiment is different from the first embodiment mainly in the configuration of the second insulating layer 220.

### [Configuration of Semiconductor Device]

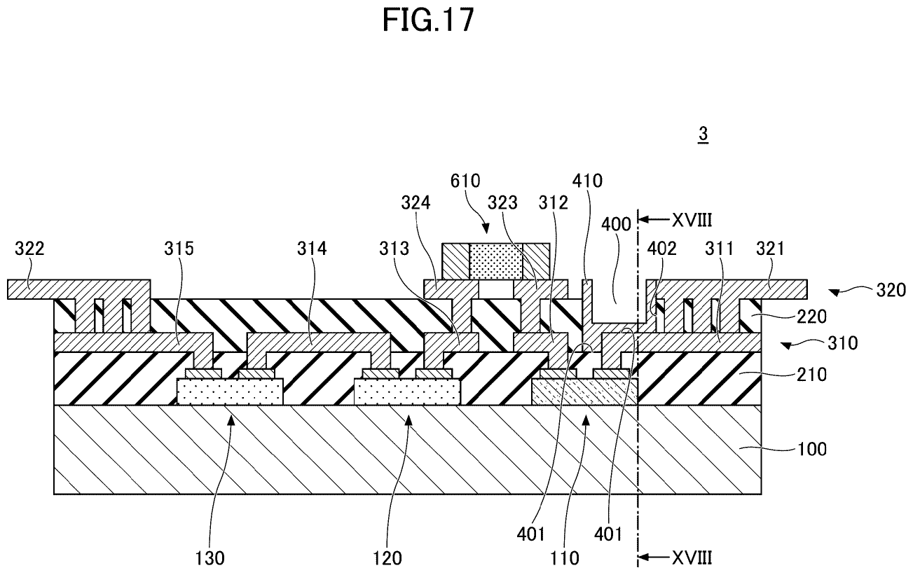

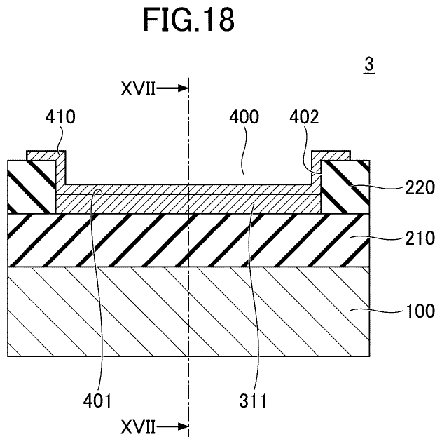

A configuration of a semiconductor device according to the third embodiment will be described. FIGS. 17 and 18 are cross-sectional views illustrating the semiconductor device according to the third embodiment. FIG. 17 corresponds to a cross-sectional view taken along line XVII-XVII in FIG. 18, and FIG. 18 corresponds to a cross-sectional view taken along line XVIII-XVIII in FIG. 17.

In a semiconductor device 3 according to the third embodiment, as illustrated in FIGS. 17 and 18, an opening 400 reaching the wiring 311 and the first insulating layer 210 is formed in the second insulating layer 220. The semiconductor device 3 includes a conductive layer 410. The material of the conductive layer 410 is, for example, copper. The conductive layer 410 is provided at a bottom surface 401 and a side wall surface 402 of the opening 400, and is in contact with the wiring 311 and the external terminal 321. A portion of the conductive layer 410 may be on or over the second insulating layer 220. The thickness of the conductive layer 410 on the wiring 311 is, for example, 30 μm to 50 μm.

Other configurations of the third embodiment are the same as those of the first embodiment.

### [Method of Manufacturing Semiconductor Device]

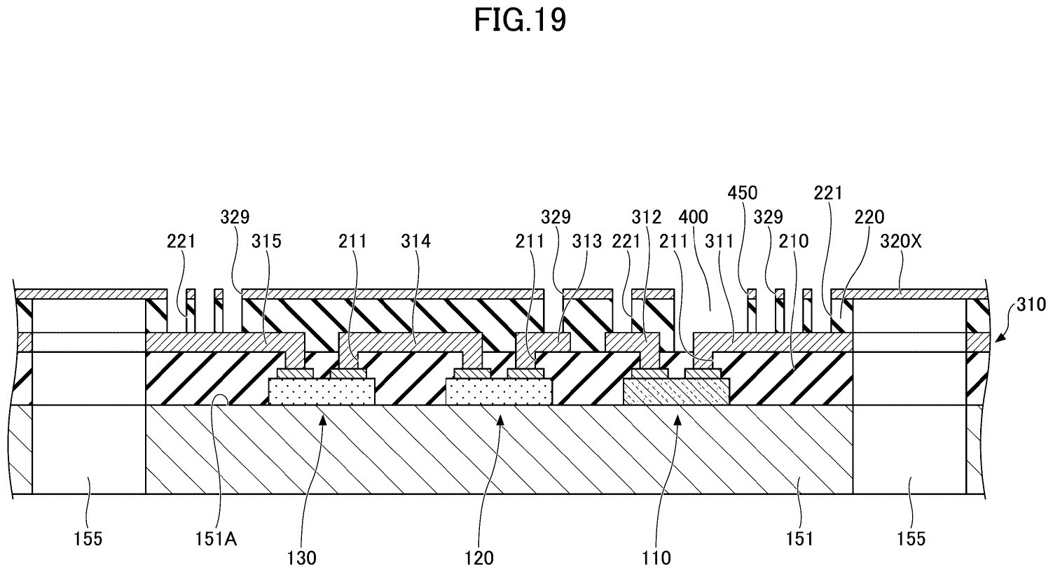

A method of manufacturing the semiconductor device according to the third embodiment will be described. FIGS. 19 to 21 are cross-sectional views illustrating the method of manufacturing the semiconductor device according to the third embodiment.

First, as in the first embodiment, the processing up to the removal of the portion of the second insulating layer 220 overlapping the slit 155 in a plan view is performed (see FIG. 9). Next, as illustrated in FIG. 19, the plurality of openings 329 and an opening 450 are formed in the metal foil 320X, and the plurality of via holes 221 and the opening 400 are formed in the second insulating layer 220. The opening 450 is formed above the region where the opening 400 is formed. The opening 450 may be formed simultaneously with the opening 329. The opening 400 may be formed simultaneously with the via hole 221. The opening 329 and the via hole 221 may be formed in the same manner as in the first embodiment.

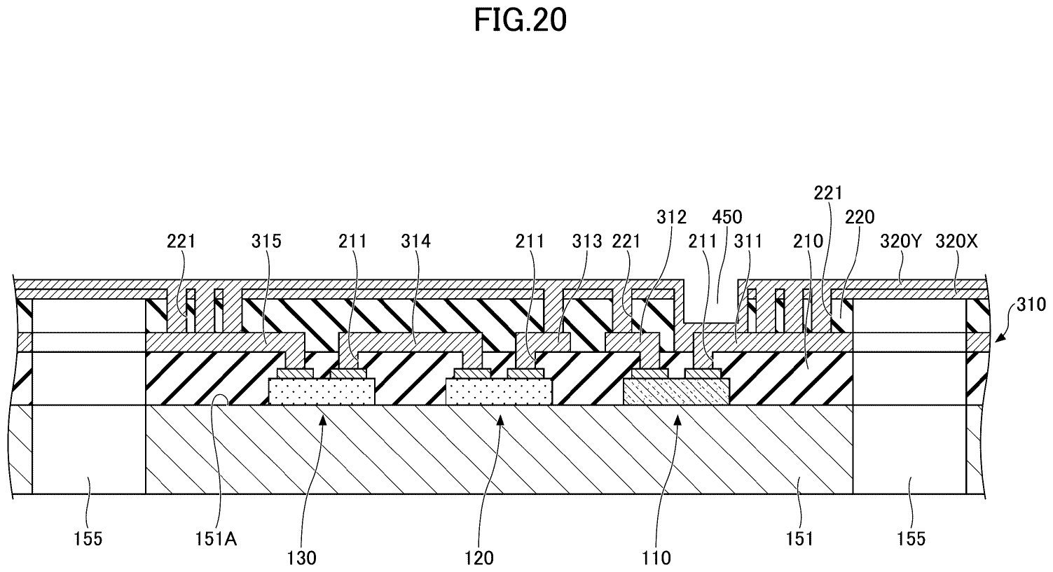

Next, as illustrated in FIG. 20, the plating layer 320Y is formed. The plating layer 320Y may be formed by the same method as the first embodiment. The plating layer 320Y may be formed at the bottom surface 401 and the side wall surface 402 of the opening 400.

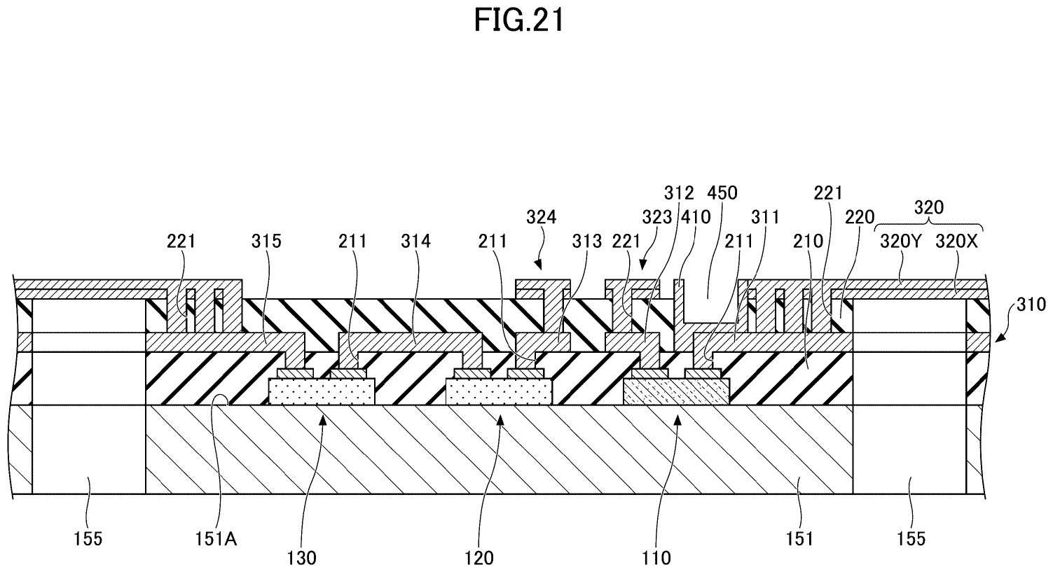

Next, as illustrated in FIG. 21, the laminate of the metal foil 320X and the plating layer 320Y is patterned to form the wirings 323 and 324 and the conductive layer 410. In addition, a portion to be the external terminal 321 and a portion to be the external terminal 322 are formed by etching performed later.

Thereafter, as in the first embodiment, the electronic component 610 is mounted, and the laminate of the metal foil 320X and the plating layer 320Y is cut by etching along the cutting-plane line 156.

In this way, the semiconductor device 3 according to the third embodiment can be manufactured.

The third embodiment also provides the same effect as the first embodiment.

When the dielectric loss of the second insulating layer 220 is higher than the dielectric loss of the first insulating layer 210, the high frequency characteristics may be lower than those when the dielectric loss of the second insulating layer 220 is equal to the dielectric loss of the first insulating layer 210. When the electrode 111 of the chip 110 is connected to the drain of the transistor included in the chip 110, the external terminal 321 functions as an output terminal. That is, the wiring 311 is connected to the output terminal. In the third embodiment, the opening 400 reaching the wiring 311 is formed in the second insulating layer 220. Thus, even when the dielectric loss of the second insulating layer 220 is higher than the dielectric loss of the first insulating layer 210, good high frequency characteristics can be obtained. For example, 3 dB gain compression points, efficiencies, and power gains can be improved compared to the first embodiment.

In addition, since the conductive layer 410 is electrically connected to the wiring 311 and the external terminal 321, the effective cross-sectional area between the wiring 311 and the external terminal 321 is increased, and the electrical resistance is reduced. Thus, the high frequency characteristics are improved also in this respect. Furthermore, since heat generated in the chip 110 is released through the conductive layer 410, the heat dissipation property is improved.

In order to obtain good high frequency characteristics, it is also considered to use a material having a dielectric loss of 0.007 or less as the material of the second insulating layer 220, as in the case of the first insulating layer 210. However, in this case, it may be difficult to appropriately form the via hole 221 in the second insulating layer 220 using an alkaline solution.

### Fourth Embodiment

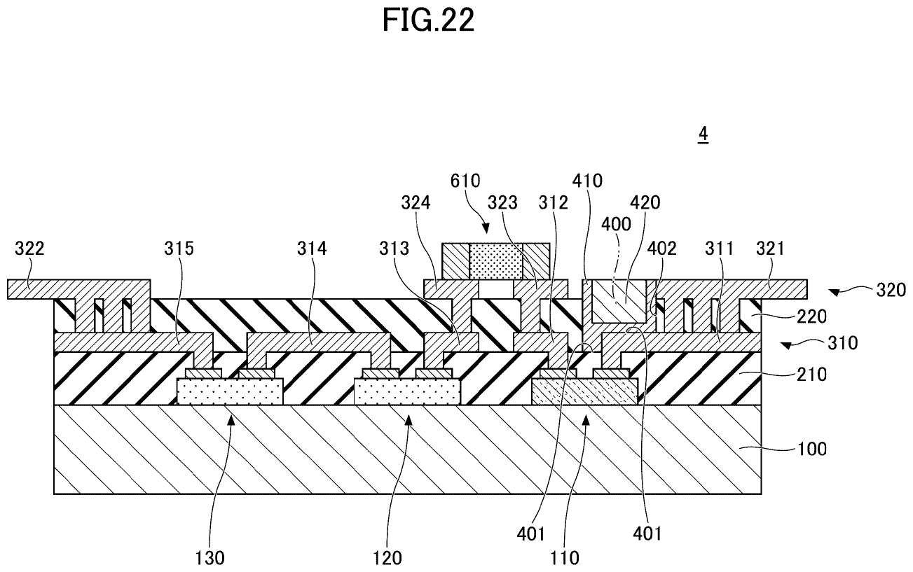

Next, a fourth embodiment will be described. The fourth embodiment is different from the third embodiment mainly in that it includes a sintered metal. FIG. 22 is a cross-sectional view illustrating a semiconductor device according to the fourth embodiment. A semiconductor device 4 according to the fourth embodiment includes a sintered metal 420 as illustrated in FIG. 22. The sintered metal 420 is provided on or above the conductive layer 410 inside the opening 400. The sintered metal 420 may include, for example, copper or silver.

Other configurations of the fourth embodiment are the same as those of the third embodiment.

The fourth embodiment also provides the same effect as the third embodiment. In addition, according to the fourth embodiment, since the sintered metal 420 is provided, the effective cross-sectional area between the wiring 311 and the external terminal 321 is further increased, and the electrical resistance is further reduced. Thus, the high frequency characteristics are further improved. Furthermore, since the heat generated in the chip 110 is released through the sintered metal 420, the heat dissipation property is further improved. Further, since the sintered metal 420 is provided, the conductive layer 410 can be protected from the entry of moisture from the outside, and the like.

### Fifth Embodiment

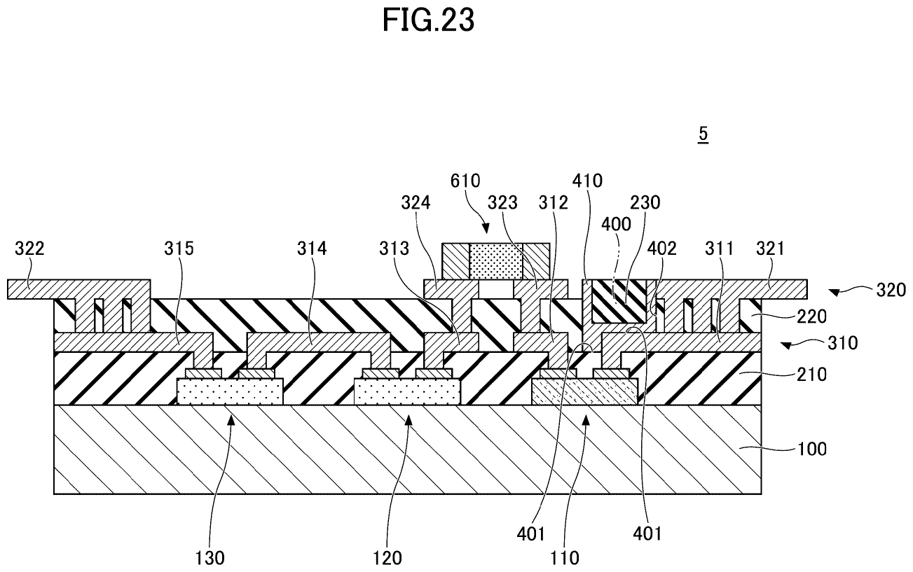

Next, a fifth embodiment will be described. The fifth embodiment is different from the third embodiment mainly in that it includes a third insulating layer. FIG. 23 is a cross-sectional view illustrating a semiconductor device according to the fifth embodiment.

A semiconductor device 5 according to the fifth embodiment includes a third insulating layer 230 as illustrated in FIG. 23. The third insulating layer 230 is provided on or above the conductive layer 410 inside the opening 400. The dielectric loss of the third insulating layer 230 is lower than the dielectric loss of the second insulating layer 220. The third insulating layer 230 includes, for example, polyphenylene ether (PPE) or liquid crystal polymer (LCP). The dielectric loss of polyphenylene ether is 0.005 or less at 10 GHz. The dielectric loss of the liquid crystal polymer is 0.003 or less at 1 GHZ.

Other configurations of the fifth embodiment are the same as those of the third embodiment.

The fifth embodiment also provides the same effect as the third embodiment. Further, according to the fifth embodiment, since the third insulating layer 230 is provided, the conductive layer 410 can be protected from the entry of moisture from the outside, and the like.

### Sixth Embodiment

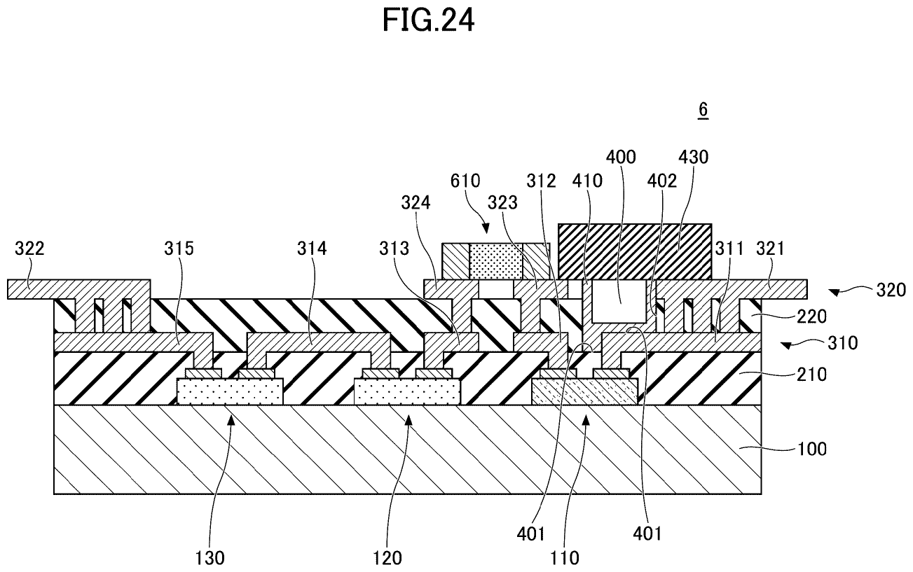

Next, a sixth embodiment will be described. The sixth embodiment is different from the third embodiment mainly in that it includes a covering member. FIG. 24 is a cross-sectional view illustrating a semiconductor device according to the sixth embodiment.

A semiconductor device 6 according to the sixth embodiment includes a covering member 430, which is solid, as illustrated in FIG. 24. The covering member 430 covers the opening 400 in a hollow state. The covering member 430 contains, for example, polyether ether ketone (PEEK), an ABS resin containing acrylonitrile, butadiene, and styrene, or an epoxy resin.

Other configurations of the sixth embodiment are the same as those of the third embodiment.

The sixth embodiment also provides the same effect as the third embodiment. According to the sixth embodiment, since the covering member 430 is provided, the conductive layer 410 can be protected from the entry of moisture from the outside, and the like.

The sixth embodiment may further include the sintered metal 420 or the third insulating layer 230.

### Seventh Embodiment

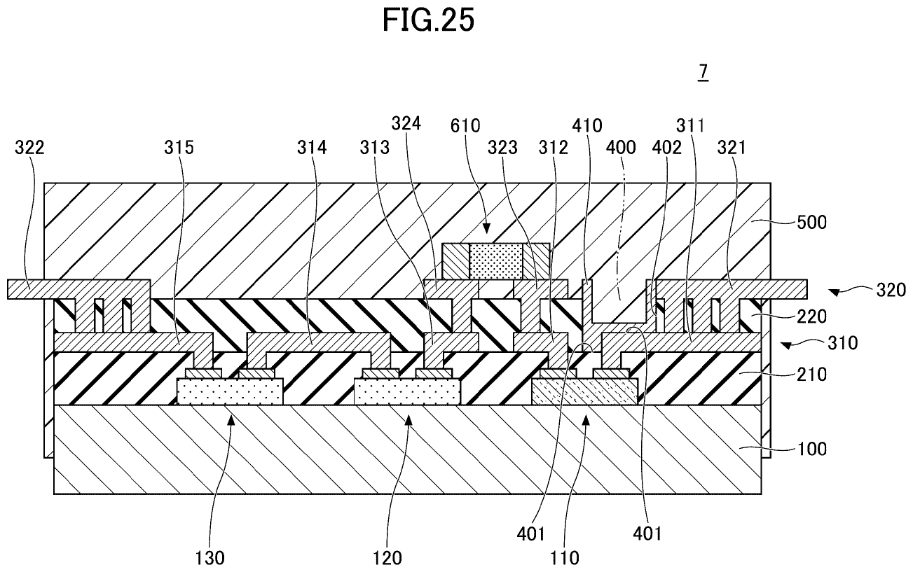

Next, a seventh embodiment will be described. The seventh embodiment is different from the third embodiment mainly in that it includes a molding member. FIG. 25 is a cross-sectional view illustrating a semiconductor device according to the seventh embodiment.

As illustrated in FIG. 25, a semiconductor device 7 according to the seventh embodiment includes the molding member 500 as in the second embodiment. Other configurations of the seventh embodiment are the same as those of the third embodiment.

The seventh embodiment also provides the same effect as the third embodiment. According to the seventh embodiment, the electronic component 610, the second wiring layer 320, the second insulating layer 220, the first wiring layer 310, and the first insulating layer 210 can be protected from the entry of moisture from the outside, and the like.

Although the embodiments have been described in detail, the present disclosure is not limited to the specific embodiments, and various modifications and changes can be made within the scope described in the claims.

What is claimed is:

1. A semiconductor device comprising:
a conductive base having a first main surface;
a semiconductor chip provided at the first main surface and including a first electrode;
a first insulating layer provided at the first main surface and covering the semiconductor chip;
a first wiring layer provided on the first insulating layer and including a first wiring electrically connected to the first electrode;
a second insulating layer provided on the first insulating layer and covering the first wiring layer; and
a second wiring layer provided on the second insulating layer and including an external terminal electrically connected to the first wiring,
wherein the external terminal extends outward beyond a side surface of the second insulating layer in a plan view perpendicular to the first main surface.

2. The semiconductor device according to claim 1,
wherein a dielectric loss of the first insulating layer is lower than a dielectric loss of the second insulating layer.

3. The semiconductor device according to claim 2,
wherein the second insulating layer has formed therein an opening reaching the first wiring.

4. The semiconductor device according to claim 3, further comprising:
a conductive layer provided at a bottom surface and a side wall surface of the opening, the conductive layer being in contact with the first wiring and the external terminal.

5. The semiconductor device according to claim 4, further comprising:
a sintered metal provided on the conductive layer.

6. The semiconductor device according to claim 4, further comprising:
a third insulating layer provided on the conductive layer,
wherein a dielectric loss of the third insulating layer is lower than the dielectric loss of the second insulating layer.

7. The semiconductor device according to claim 3, further comprising:
a covering member covering the opening.

8. The semiconductor device according to claim 1, further comprising:
a molding member covering the second wiring layer, the second insulating layer, the first wiring layer, and the first insulating layer.

9. The semiconductor device according to claim 2, further comprising:
a molding member covering the second wiring layer, the second insulating layer, the first wiring layer, and the first insulating layer,
wherein a dielectric loss of the molding member is lower than the dielectric loss of the second insulating layer.

10. The semiconductor device according to claim 1,
wherein the second wiring layer includes a second wiring, and
wherein the semiconductor device includes an electronic component electrically connected to the second wiring.

11. The semiconductor device according to claim 10,
wherein the semiconductor chip includes a second electrode, and
wherein the first wiring layer includes a third wiring electrically connected to the second electrode and the second wiring.

12. A method of manufacturing a semiconductor device, the method comprising:
providing a semiconductor chip at a first main surface of a conductive base having the first main surface, the semiconductor chip including a first electrode;
providing a first insulating layer at the first main surface configured to cover the semiconductor chip;
providing a first wiring layer on the first insulating layer, the first wiring layer including a first wiring electrically connected to the first electrode;
providing a second insulating layer on the first insulating layer configured to cover the first wiring layer; and
providing a second wiring layer on the second insulating layer, the second wiring layer including an external terminal electrically connected to the first wiring,
wherein the external terminal extends outward beyond a side surface of the second insulating layer in a plan view perpendicular to the first main surface.
